(19) United States
(12) Patent Application Publication
(10) Pub. No.: US 2009/0301562 A1
(43) Pub. Date: Dec. 10, 2009

(54) HIGH EFFICIENCY PHOTOVOLTAIC CELL AND MANUFACTURING METHOD

(75) Inventor: HOWARD W.H. LEE, Saratoga, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Stion Corporation, San Jose, CA (US)

(21) Appl. No.: 12/475,858

(22) Filed: Jun. 1, 2009

Related U.S. Application Data
(60) Provisional application No. 61/059,253, filed on Jun. 5, 2008.

(51) Int. Cl. H01L 31/00; H01L 31/18

(52) U.S. Cl. 136/256; 438/73; 257/E21.158

(57) ABSTRACT

A method for forming a thin film photovoltaic device includes providing a transparent substrate comprising a surface region and forming a first electrode layer overlying the surface region. Additionally, the method includes forming a copper indium material comprising an atomic ratio of Cu:In ranging from about 1.35:1 to about 1.60:1 by at least sputtering a target comprising an indium copper material. The method further includes subjecting the copper indium material to thermal treatment process in an environment containing a sulfur bearing species. Furthermore, the method includes forming a copper indium disulfide material from at least the thermal treatment process of the copper indium material. Moreover, the method includes forming a window layer overlying the copper indium disulfide material.

### CROSS-REFERENCES TO RELATED APPLICATIONS

This application claims priority to U.S. Provisional Patent Application No. 61/059,253, filed Jun. 5, 2008, entitled “HIGH EFFICIENCY PHOTOVOLTAIC CELL AND MANUFACTURING METHOD” by inventor Howard W. H. Lee, commonly assigned and incorporated by reference herein for all purposes.

### STATEMENT AS TO RIGHTS TO INVENTIONS MADE UNDER FEDERALLY SPONSORED RESEARCH OR DEVELOPMENT

Not Applicable

### REFERENCE TO A “SEQUENCE LISTING,” A TABLE, OR A COMPUTER PROGRAM LISTING APPENDIX SUBMITTED ON A COMPACT DISK.

Not Applicable

### BACKGROUND OF THE INVENTION

The present invention relates generally to photovoltaic materials and manufacturing method. More particularly, the present invention provides a method and structure for manufacture of high efficiency thin film photovoltaic cells. Merely by way of example, the present method and materials include absorber materials made of copper indium disulfide species, copper tin sulfide, iron disulfide, or others for single junction cells or multi-junction cells.

From the beginning of time, mankind has been challenged to find way of harnessing energy. Energy comes in the forms such as petrochemical, hydroelectric, nuclear, wind, biomass, solar, and more primitive forms such as wood and coal. Over the past century, modern civilization has relied upon petrochemical energy as an important energy source. Petrochemical energy includes gas and oil. Gas includes lighter forms such as butane and propane, commonly used to heat homes and serve as fuel for cooking. Gas also includes gasoline, diesel, and jet fuel, commonly used for transportation purposes. Heavier forms of petrochemicals can also be used to heat homes in some places. Unfortunately, the supply of petrochemical fuel is limited and essentially fixed based upon the amount available on the planet Earth. Additionally, as more people use petroleum products in growing amounts, it is rapidly becoming a scarce resource, which will eventually become depleted over time.

More recently, environmentally clean and renewable sources of energy have been desired. An example of a clean source of energy is hydroelectric power. Hydroelectric power is derived from electric generators driven by the flow of water produced by dams such as the Hoover Dam in Nevada. The electric power generated is used to power a large portion of the city of Los Angeles in California. Clean and renewable sources of energy also include wind, waves, biomass, and the like. That is, windmills convert wind energy into more useful forms of energy such as electricity. Still other types of clean energy include solar energy. Specific details of solar energy can be found throughout the present background and more particularly below.

Solar energy technology generally converts electromagnetic radiation from the sun to other useful forms of energy. These other forms of energy include thermal energy and electrical power. For electrical power applications, solar cells are often used. Although solar energy is environmentally clean and has been successful to a point, many limitations remain to be resolved before it becomes widely used throughout the world. As an example, one type of solar cell uses crystalline materials, which are derived from semiconductor material ingots. These crystalline materials can be used to fabricate optoelectronic devices that include photovoltaic and photodiode devices that convert electromagnetic radiation into electrical power. However, crystalline materials are often costly and difficult to make on a large scale. Additionally, devices made from such crystalline materials often have low energy conversion efficiencies. Other types of solar cells use “thin film” technology to form a thin film of photosensitive material to be used to convert electromagnetic radiation into electrical power. Similar limitations exist with the use of thin film technology in making solar cells. That is, efficiencies are often poor. Additionally, film reliability is often poor and cannot be used for extensive periods of time in conventional environmental applications. Often, thin films are difficult to mechanically integrate with each other. These and other limitations of these conventional technologies can be found throughout the present specification and more particularly below.

From the above, it is seen that improved techniques for manufacturing photovoltaic materials and resulting devices are desired.

### BRIEF SUMMARY OF THE INVENTION

According to embodiments of the present invention, a method and a structure for forming thin film semiconductor materials for photovoltaic applications are provided. More particularly, the present invention provides a method and structure for forming semiconductor materials used for the manufacture of high efficiency photovoltaic cells. Merely by way of example, the present method and materials include absorber materials made of copper indium disulfide species, copper tin sulfide, iron disulfide, or others for single junction cells or multi-junction cells.

In a specific embodiment, a method for forming a thin film photovoltaic device includes providing a transparent substrate comprising a surface region. The method also includes forming a first electrode layer overlying the surface region and forming a copper layer overlying the first electrode layer. Additionally, the method includes forming an indium layer overlying the copper layer to form a multi-layered structure and subjecting at least the multi-layered structure to thermal treatment process in an environment containing a sulfur bearing species. The method further includes forming a copper indium disulfide material from at least the treatment process of the multi-layered structure. The copper indium disulfide material includes an atomic ratio of copper:indium (Cu:In) ranging from about 1.35:1 to about 1.60:1. Furthermore, the method includes forming a window layer overlying the copper indium disulfide material.

In another specific embodiment, a method for forming a thin film photovoltaic device includes providing a transparent substrate comprising a surface region and forming a first electrode layer overlying the surface region. Additionally, the method includes forming a copper indium material comprising an atomic ratio of Cu:In ranging from about 1.35:1 to about 1.60:1 by at least sputtering a target comprising an indium copper material. The method further includes subjecting the copper indium material to thermal treatment process in an environment containing a sulfur bearing species. Furthermore, the method includes forming a copper indium disulfide material from at least the thermal treatment process of the copper indium material. Moreover, the method includes forming a window layer overlying the copper indium disulfide material.

In a specific embodiment, the present invention provides a method for forming a thin film photovoltaic device. The method includes providing a transparent substrate comprising a surface region. The method forms a first electrode layer overlying the surface region of the transparent substrate and subjects one or more target materials including at least a copper material and an indium material with a plurality of particles comprising one or more inert species and an hydrogen disulfide species to release a plurality of copper species and indium species according to a preferred embodiment. The method includes forming a copper indium disulfide layer of material overlying the first electrode layer. In one embodiment, the copper indium disulfide material comprises an atomic ratio of copper:indium (Cu:In) ranging from about 1.35:1 to about 1.60:1. In another embodiment, the copper indium disulfide material comprises an atomic ratio of Cu:In ranging from about 1.2:1 to about 2:1. In a preferred embodiment, the method includes forming a window layer overlying the copper indium disulfide material.

In another specific embodiment, a method for forming a thin film photovoltaic device includes providing a substrate comprising a surface region. The method also includes forming a first electrode layer overlying the surface region and forming a copper layer overlying the first electrode layer. Additionally, the method includes forming an indium layer overlying the copper layer to form a multi-layered structure and subjecting at least the multi-layered structure to thermal treatment process in an environment containing a sulfur bearing species. The method further includes forming a copper indium disulfide material from at least the treatment process of the multi-layered structure. The copper indium disulfide material is characterized by a thickness ranging from about 1 micron to about 2 microns and an atomic ratio of copper:indium (Cu:In) from about 1.4:1 to about 1.6:1. Furthermore, the method includes forming a window layer overlying the copper indium disulfide material. The copper indium disulfide material forms an absorber layer of a photovoltaic device characterized by an efficiency of about 10% and greater under a standard test condition.

In yet another specific embodiment, the present invention provides a thin film photovoltaic device. The device includes a substrate comprising a surface region and a first electrode layer overlying the surface region. Additionally, the device includes an absorber layer including a copper indium disulfide material characterized by a thickness ranging from 1 micron to 2 microns and a copper-to-indium atomic ratio ranging from about 1.4:1 to about 1.6:1. Moreover, the device includes a window layer overlying the absorber layer and a characteristics of an energy conversion efficiency of about 10% and greater.

Still further, the present invention provides a thin film photovoltaic device, which can be configured in a bifacial manner. The bifacial device can be configured to a tandem cell, or other multi-cell configuration. In a specific embodiment, the present device has a transparent substrate comprising a surface region and a first electrode layer overlying the surface region. The device also has a copper indium disulfide material on the first electrode layer. In a preferred embodiment, the copper indium disulfide material is characterized by a copper-to-indium atomic ratio ranging from about 1.35:1 to about 1.60:1. The device also has a window layer overlying the copper indium disulfide material. In a preferred embodiment, the device also has an efficiency of about 10% and greater and also has a bandgap ranging from about 1.4 eV to 1.5 eV, and preferably 1.45 eV to about 1.5 eV.

Many benefits are achieved by ways of present invention. For example, the present invention uses starting materials that are commercially available to form a thin film of semiconductor bearing material overlying a suitable substrate member. The thin film of semiconductor bearing material can be further processed to form a semiconductor thin film material of desired characteristics, such as atomic stoichiometry, impurity concentration, carrier concentration, doping, and others. Additionally, the present method uses environmentally friendly materials that are relatively less toxic than other thin-film photovoltaic materials. In a specific embodiment, the present device including the absorber (CuInS2) is characterized by a bandgap at between about 1.45 eV to 1.5 eV, but can be others. In a specific embodiment, the bandgap can be higher for a CuInS2 absorber including a gallium species, which has been alloyed. In a preferred embodiment, the present method and device is bifacial and can be configured for a tandem or other multilevel cell arrangement. The bifacial cell would act as an upper or top cell according to a specific embodiment. Depending on the embodiment, one or more of the benefits can be achieved. These and other benefits will be described in more detailed throughout the present specification and particularly below.

Merely by way of example, the present method and materials include absorber materials made of copper indium disulfide species, copper tin sulfide, iron disulfide, or others for single junction cells or multi-junction cells.

### BRIEF DESCRIPTION OF THE DRAWINGS

FIGS. 1-7 are schematic diagrams illustrating a method and structure for forming a thin film photovoltaic device according to an embodiment of the present invention; and

FIG. 8 is a simplified flow chart summarizing a method for forming a thin film photovoltaic device according to an embodiment of the present invention.

FIG. 9 is an exemplary solar cell I-V characteristics plot measured from a copper indium disulfide based thin film photovoltaic cell according to an embodiment of the present invention.

### DETAILED DESCRIPTION OF THE INVENTION

According to embodiments of the present invention, a method and a structure for forming semiconductor materials for photovoltaic applications are provided. More particularly, the present invention provides a method for manufacturing thin film photovoltaic devices. Merely by way of example, the method has been used to provide a copper indium disulfide thin film material for high efficiency solar cell application. But it would be recognized that the present invention has a much broader range of applicability, for example, embodiments of the present invention may be used to form other semiconducting thin films or multilayers comprising iron sulfide, cadmium sulfide, zinc selenide, and others, and metal oxides such as zinc oxide, iron oxide, copper oxide, and others.

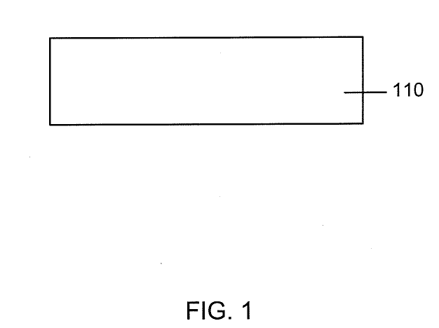

FIG. 1 is a schematic diagram illustrating a process of a method for forming a thin film photovoltaic device according to an embodiment of the present invention. The diagram is merely an example, which should not unduly limit the claims herein. One skilled in the art would recognize other variations, modifications, and alternatives. As shown in FIG. 1, a substrate 110 is provided. In one embodiment, the substrate 110 includes a surface region 112 and is held in a process stage within a process chamber (not shown). In another embodiment, the substrate 110 is an optically transparent solid material. For example, the substrate 110 can be a glass, quartz, fused silica. Or the substrate can be other materials, transparent or non-transparent, including a plastic, or metal, or foil, or semiconductor, or other composite materials. Of course there can be other variations, modifications, and alternatives.

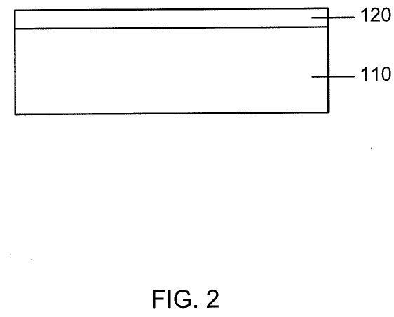

FIG. 2 is a schematic diagram illustrating a process of the method for forming a thin film photovoltaic device according to an embodiment of the present invention. The diagram is merely an example, which should not unduly limit the claims herein. One skilled in the art would recognize other variations, modifications, and alternatives. As shown in FIG. 2, a process for forming a thin film photovoltaic device is to form an electrode layer. In particular, an electrode layer 120 is formed overlying the surface region 112 of the substrate 110. For example, the electrode layer 120 can be made of molybdenum using sputtering, evaporation (e.g., electron beam), electro plating, combination of these, and the like according to a specific embodiment. The thickness of the electrode layer can be ranged from 100 nm to 2 micron and others, characterized by resistivity of about 100 Ohm/cm² to 10 Ohm/cm² and less according to a specific embodiment. In a preferred embodiment, the electrode is made of molybdenum or tungsten, but can be others like copper, chromium, aluminum, nickel, or platinum. Of course, there can be other variations, modifications, and alternatives.

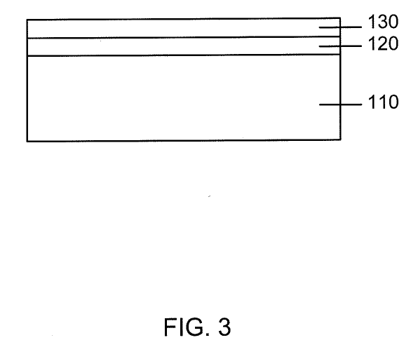

FIG. 3 is a schematic diagram illustrating a process of the method for forming a thin film photovoltaic device according to an embodiment of the present invention. The diagram is merely an example, which should not unduly limit the claims herein. One skilled in the art would recognize other variations, modifications, and alternatives. As shown is a process of forming a copper layer overlying the electrode layer formed in last process. In particular, a copper (Cu) layer 130 is formed overlying the electrode layer 120. For example, the copper layer is formed using a sputtering process. In one example, a DC magnetron sputtering process can be used to deposit Cu layer 130 onto the electrode layer 120 under a following condition. The deposition pressure (using Ar gas) is controlled to be about 6.2 mTorr. The gas flow rate is set to about 32 sccm. The deposition temperature can be just at room temperature without need of intentionally heating the substrate. Of course, minor heating may be resulted due to the plasma generated during the deposition. Additionally, the DC power supply of about 115 W may be required. According to certain embodiments, DC power in a range from 100 W to 150 W is suitable depending specific cases with different materials. The full deposition time for a Cu layer of 330 nm thickness is about 6 minutes or more. Of course, the deposition condition can be varied and modified according to a specific embodiment. For example, the sputtering process of Cu can be performed using a Cu—Ga alloy target. Therefore, the Cu layer 130 can contain at least partially a desirable and adjustable amount of Ga species within the final metal precursor film.

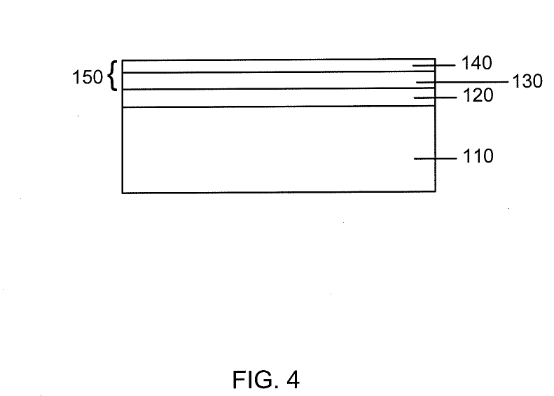

FIG. 4 is a schematic diagram illustrating a process of the method for forming a thin film photovoltaic device according to an embodiment of the present invention. The diagram is merely an example, which should not unduly limit the claims herein. One skilled in the art would recognize other variations, modifications, and alternatives. As shown, a process of providing an indium (In) layer overlying the copper (Cu) layer is illustrated. In particular, the indium layer 140 is formed overlying the copper layer 130. For example, the indium layer is deposited over the copper layer using a sputtering process. In one example, a DC magnetron sputtering process can be used to deposit In layer 140 overlying the Cu layer 130 under a similar condition for depositing the Cu layer. In another example, the sputtering process to deposit In layer 140 can be performed by using an In—Ga alloy target to form an In—Ga layer overlying the Cu layer 130. The Ga content can be adjusted to a desired level by selecting a proper concentration ratio in the In—Ga alloy target and some deposition conditions. This Ga content at least partially contributes final Ga species and ratio of Cu/(In+Ga) within the metal precursor film for forming the absorber layer of the solar cell. The deposition time for the indium layer may be shorter than that for Cu layer. For example, 2 minutes and 45 seconds may be enough for depositing an In layer of about 410 nm in thickness. In another example, the indium layer is provided overlying the copper layer by an electro plating process, or others dependent on specific embodiment.

According to embodiments of the present invention, FIGS. 1 through 4 illustrate a formation of a multilayered structure 150 comprising copper and indium on a transparent substrate provided by processes of a method of forming a thin film photovoltaic device. In one embodiment, the copper layer 130 as well as the indium layer 140 are provided with an stoichiometric control to ensure that the formed multilayered structure 150 is a Cu-rich material with an atomic ratio of Cu:In greater than 1 therein. For example, the atomic ratio of Cu:In can be in a range from 1.2:1 to 2.0:1. In one implementation, the atomic ratio of Cu:In is between 1.35:1 and 1.60:1. In another implementation, the atomic ratio of Cu:In is selected to be about 1.55:1. In a specific embodiment, the formation process of indium layer 140 substantially causes no change in atomic stoichiometry in the copper layer 130 formed earlier. In another specific embodiment, the formation process of the indium layer 140 is performed earlier overlying the electrode layer 120 while the formation process of the copper layer 130 is performed later overlying the indium layer 140.

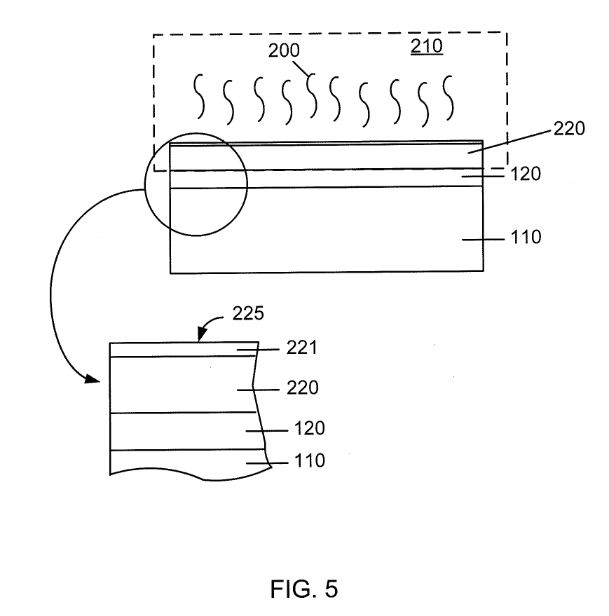

FIG. 5 is a schematic diagram illustrating a process of the method for forming a thin film photovoltaic device according to an embodiment of the present invention. The diagram is merely an example, which should not unduly limit the claims herein. One skilled in the art would recognize other variations, modifications, and alternatives. As shown, the formed multilayered structure 150 comprising at least an indium layer 140 over a copper layer 130 is subjected to a thermal treatment process 200 in an environment containing a sulfur bearing species 210 at an adequate pressure and at a temperature of about 400 Degrees Celsius to about 600 Degrees Celsius for about three to fifteen minutes for a rapid thermal process according to a specific embodiment. In one example, the sulfur bearing species are in a fluid phase. As an example, the sulfur can be provided in a solution, which has dissolved Na₂S, CS₂, (NH₄)₂S, thiosulfate, and others. In another example, the sulfur bearing species 210 are hydrogen sulfide in gas phase. In other embodiments, the sulfur can be provided in a solid phase. In a solid phase, elemental sulfur can be heated and allowed to boil, which vaporizes into a gas phase, e.g., Sn. In a specific embodiment, the gas phase is allowed to react to the indium/copper layers. In other embodiments, other combinations of sulfur species can be used. Of course, the thermal treatment process 200 includes certain predetermined ramp-up and ramp down period with certain predetermined speed for temperature changes. For example, the thermal treatment process is a rapid thermal annealing process. The hydrogen sulfide gas is provided through one or more entry valves with flow rate control into the process chamber where the hydrogen sulfide gas pressure is under controlled by one or more pumps. Of course, there can be other variations, modifications, and alternatives.

In a specific embodiment, the sulfur can be provided as a layer overlying the indium and copper layers or copper and indium layers. In a specific embodiment, the sulfur material is provided as a thin layer or patterned layer. Depending upon the embodiment, the sulfur can be provided as a slurry, powder, solid material, gas, paste, or other suitable form. Of course, there can be other variations, modifications, and alternatives.

Referring to the FIG. 5, the thermal treatment process 200 causes a reaction between copper indium material within the multilayered structure 150 and the sulfur bearing species 210, thereby forming a layer of copper indium disulfide material (or a copper indium disulfide thin film) 220. In one example, the copper indium disulfide material or copper indium disulfide thin film 220 is transformed by incorporating sulfur ions/atoms stripped or decomposed from the sulfur bearing species into the multilayered structure 150 with indium atoms and copper atoms mutually diffused therein. In one embodiment, the thermal treatment process 200 would result in a formation of a cap layer over the transformed copper indium disulfide material 220. The cap layer contains a thickness of substantially copper sulfide material 221 but substantially free of indium atoms. The copper sulfide material 221 includes a surface region 225 of the same copper sulfide material substantially free of indium atoms. In a specific embodiment, the formation of this cap layer is under a Cu-rich conditions for the original Cu—In bearing multilayered structure 150. Depending on the applications, the thickness of the copper sulfide material 221 is on an order of about five to ten nanometers and greater based on original multilayered structure 150 with indium layer 140 overlying copper layer 130. Of course, there can be other variations, modifications, and alternatives.

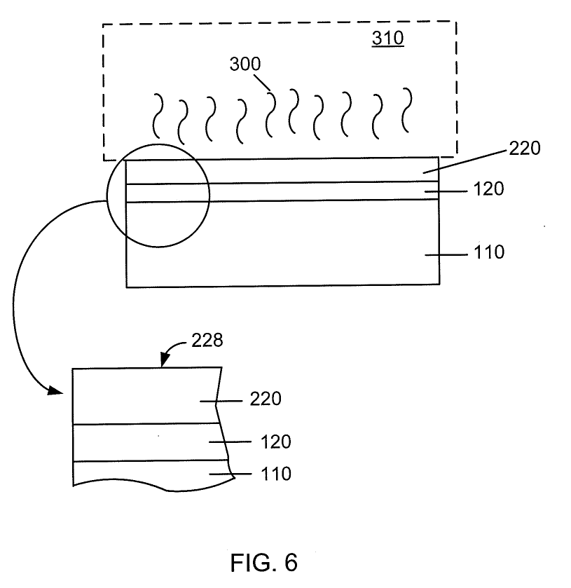

FIG. 6 is a schematic diagram illustrating a process of the method for forming a thin film photovoltaic device according to an embodiment of the present invention. The diagram is merely an example, which should not unduly limit the claims herein. One skilled in the art would recognize other variations, modifications, and alternatives. As shown in FIG. 6, a dip process 300 is performed to the copper sulfide material 221 that covers the copper indium disulfide thin film 220. In particular, the dip process is performed by exposing the surface region 225 to 1 about 10 weight % solution of potassium cyanide 310 according to a specific embodiment. The potassium cyanide acts as an etchant that is capable of selectively removing copper sulfide material 221. The etching process starts from the exposed surface region 225 and down to the thickness of the copper sulfide material 221 and substantially stopped at the interface between the copper sulfide material 221 and copper indium disulfide material 220. As a result the copper sulfide cap layer 221 is selectively removed by the etching process so that a new surface region 228 of the remaining copper indium disulfide thin film 220 is exposed according to a specific embodiment. In a preferred embodiment, the etch selectivity is about 1:100 or more between copper sulfide and copper indium disulfide. In other embodiments, other selective etching species can be used. In a specific embodiment, the etching species can be hydrogen peroxide. In other embodiments, other techniques including electro-chemical etching, plasma etching, sputter-etching, or any combination of these can be used. In a specific embodiment, the copper sulfide material can be mechanically removed, chemically removed, electrically removed, or any combination of these, among others. In a specific embodiment, the absorber layer made of copper indium disulfide is about 1 to 10 microns, but can be others. Of course, there can be other variations, modifications, and alternatives.

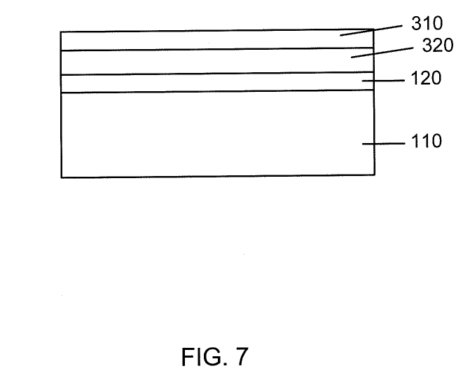

FIG. 7 is a schematic diagram illustrating a process of the method for forming a thin film photovoltaic device according to an embodiment of the present invention. The diagram is merely an example, which should not unduly limit the claims herein. One skilled in the art would recognize other variations, modifications, and alternatives. As shown in FIG. 7, a p-type copper indium disulfide film 320 is formed. In certain embodiments, the previously-formed copper indium disulfide material 220 has possessed a p-type semiconducting characteristic and is substantially the same as the p-type copper indium disulfide film 320. In another embodiment, the copper indium disulfide material 220 is subjected to additional doping process to adjust p-type impurity density therein for the purpose of optimizing I-V characteristic of the high efficiency thin film photovoltaic devices. In one example, aluminum species are mixed into the copper indium disulfide material 220. In another example, the copper indium disulfide material 220 is mixed with a copper indium aluminum disulfide material to form the film 320. Of course, there can be other variations, modifications, and alternatives.

Subsequently, a window layer 310 is formed overlying the p-type copper indium disulfide material 320. The window layer 310 can be selected from a group materials consisting of a cadmium sulfide (CdS), a zinc sulfide (ZnS), zinc selinium (ZnSe), zinc oxide (ZnO), zinc magnesium oxide (ZnMgO), or others and may be doped with impurities for conductivity, e.g., n⁺ type. The window layer 310 is intended to serve another part of a PN-junction associated with a photovoltaic cell. Therefore, the window layer 310, during or after its formation, is heavily doped to form a n⁺-type semiconductor layer. In one example, indium species are used as the doping material to cause formation of the n⁺-type characteristic associated with the window layer 310. In another example, the doping process is performed using suitable conditions. In a specific embodiment, ZnO window layer that is doped with aluminum can range from about 200 to 500 nanometers. Of course, there can be other variations, modifications, and alternative

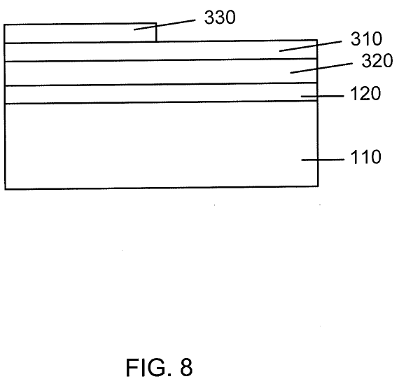

FIG. 8 is a schematic diagram illustrating a process of the method for forming a thin film photovoltaic device according to an embodiment of the present invention. The diagram is merely an example, which should not unduly limit the claims herein. One skilled in the art would recognize other variations, modifications, and alternatives. As shown in FIG. 8, a conductive layer 330 is added at least partially on top of the window layer 310 to form a top electrode layer for the photovoltaic device. In one embodiment, the conductive layer 330 is a transparent conductive oxide TCO layer. For example, TCO can be selected from a group consisting of In₂O₃:Sn (ITO), ZnO:Al (AZO), SnO₂:F (TFO), and can be others. In another embodiment, the formation of the TCO layer is followed a certain predetermined pattern for effectively carried out the function of top electrode layer for the photovoltaic device with considerations of maximizing the efficiency of the thin film based photovoltaic devices. In a specific embodiment, the TCO can also act as a window layer, which essentially eliminates a separate window layer. Of course there can be other variations, modifications, and alternatives.

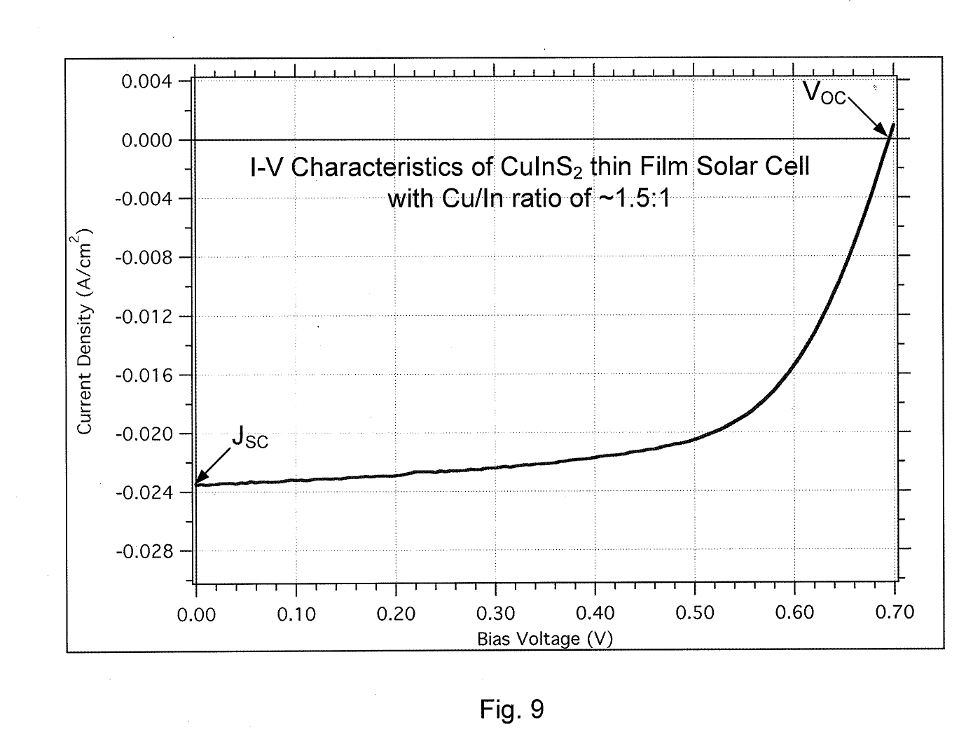

FIG. 9 is an exemplary solar cell I-V characteristics plot measured from a copper indium disulfide based thin film photovoltaic cell according to an embodiment of the present invention. The diagram is merely an example, which should not unduly limit the claims herein. One skilled in the art would recognize other variations, modifications, and alternatives. As shown in FIG. 9, a current density of a high efficiency copper indium disulfide thin film photovoltaic cell made according to an embodiment of the present invention is plotted against a bias voltage. The curve intersects the y-axis with a short circuit current value at about 0.0235 A/cm² and intersects a zero current line with a bias at about 0.69 V. The corresponding photovoltaic cell has an absorber layer made from copper indium disulfide thin film according to an embodiment of the present invention. In particular, the absorber layer is about 1.5 μm in thickness and an atomic ratio of Cu:In at about 1.5:1. Based on standard formula, a cell conversion efficiency η can be estimated:

$$η = \frac{{J}_{SC} \cdot {V}_{OC} \cdot FF}{{P}_{i n} ( AM 1.5 )}$$

where J_{SC} is the short circuit current density of the cell, V_{OC} is the open circuit bias voltage applied, FF is the so-called fill factor defined as the ratio of the maximum power point divided by the open circuit voltage (Voc) and the short circuit current (J_{SC}). The input light irradiance (Pᵢₙ, in W/m²) under standard test conditions [i.e., STC that specifies a temperature of 25° C. and an irradiance of 1000 W/m2 with an air mass 1.5 (AM1.5) spectrum.] and the surface area of the solar cell (in m²). Thus, a 10.4% efficiency can be accurately estimated for this particular cell made from a method according to embodiments of the present invention. In a specific embodiment, the bandgap is about 1.45 eV to 1.5 eV. Of course, there can be other variations, modifications, and alternatives.

Although the above has been illustrated according to specific embodiments, there can be other modifications, alternatives, and variations. It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for forming a thin film photovoltaic device, the method comprising:
providing a transparent substrate comprising a surface region;
forming a first electrode layer overlying the surface region;
forming a copper layer overlying the first electrode layer;
forming an indium layer overlying the copper layer to form a multi-layered structure;
subjecting at least the multi-layered structure to thermal treatment process in an environment containing a sulfur bearing species;
forming a copper indium disulfide material from at least the treatment process of the multi-layered structure, the copper indium disulfide material comprising a copper-to-indium atomic ratio ranging from about 1.35:1 to about 1.60:1; and
forming a window layer overlying the copper indium disulfide material.

2. The method of claim 1 wherein the copper indium disulfide material comprises a thickness of copper sulfide material having a copper sulfide surface region.

3. The method of claim 2 further comprising removing the thickness of copper sulfide material.

4. The method of claim 3 wherein the removing comprises using a solution of potassium cyanide to selectively remove the thickness of copper sulfide material.

5. The method of claim 1 wherein the window layer is selected from a group consisting of a cadmium sulfide, a zinc sulfide, zinc selinium, zinc oxide, or zinc magnesium oxide.

6. The method of claim 5 further comprising forming a transparent conductive oxide overlying a portion of the window layer.

7. The method of claim 1 wherein the forming of the copper layer is provided by a sputtering process.

8. The method of claim 1 wherein the forming of the copper layer is provided by a plating process.

9. The method of claim 1 wherein the forming of the indium layer is provided by a sputtering process.

10. The method of claim 1 wherein the forming of the indium layer is provided by a plating process.

11. The method of claim 1 wherein the copper indium disulfide has a p-type semiconductor characteristic.

12. The method of claim 1 wherein the window layer comprises an n⁺-type semiconductor characteristic.

13. The method of claim 1 further comprising introducing an indium species in the window layer to cause formation of an n⁺-type semiconductor characteristic.

14. The method of claim 1 wherein the copper indium disulfide is mixed with a copper indium aluminum disulfide.

15. The method of claim 1 wherein the sulfide bearing species comprise hydrogen sulfide in fluid phase.

16. A method for forming a thin film photovoltaic device, the method comprising:
providing a transparent substrate comprising a surface region;
forming a first electrode layer overlying the surface region;
forming a copper indium material comprising an atomic ratio of Cu:In ranging from about 1.35:1 to about 1.60:1 by at least sputtering a target comprising an indium copper material;
subjecting the copper indium material to thermal treatment process in an environment containing a sulfur bearing species;
forming a copper indium disulfide material from at least the thermal treatment process of the copper indium material; and
forming a window layer overlying the copper indium disulfide material.

17. The method of claim 16 wherein the window layer is selected from a group consisting of a cadmium sulfide, a zinc sulfide, zinc selinium, zinc oxide, or zinc magnesium oxide.

18. The method of claim 16 further comprising forming a transparent conductive oxide overlying a portion of the window layer.

19. The method of claim 16 wherein the copper indium disulfide material has a p-type semiconductor characteristic.

20. The method of claim 16 wherein the window layer comprises n⁺-type semiconductor characteristic.

21. The method of claim 16 further comprising introducing an indium species in the window layer to cause formation of an n⁺-type semiconductor characteristic.

22. The method of claim 16 wherein the sulfur bearing species comprise hydrogen sulfide.

23. A method for forming a thin film photovoltaic device, the method comprising:
providing a transparent substrate comprising a surface region;
forming a first electrode layer overlying the surface region of the transparent substrate;
subjecting one or more target materials including at least a copper material and an indium material with a plurality of particles comprising inert species and an hydrogen disulfide species to release a plurality of copper species and indium species;
forming a copper indium disulfide layer of material overlying the first electrode layer, the copper indium disulfide material comprising an atomic ratio of copper:indium ranging from about 1.35:1 to about 1.60:1; and
forming a window layer overlying the copper indium disulfide material.

24. The method of claim 23 further comprising reacting one or more of the plurality of copper species with one or more of the plurality of indium species with one or more of the hydrogen disulfide species to cause formation of the copper indium disulfide layer.

25. The method of claim 23 wherein the copper material is derived from a first target and the indium material is derived from a second target.

26. The method of claim 23 wherein the window layer is selected from a group consisting of a cadnium sulfide, a zinc sulfide, zinc selinium, zinc oxide, or zinc magnesium oxide.

27. The method of claim 26 further comprising forming a transparent conductive oxide overlying a portion of the window layer.

28. The method of claim 23 further comprising maintaining a vacuum within a spatial volume housing the one or more target materials.

29. The method of claim 23 wherein the copper material is characterized by a purity of about 99.99% or greater.

30. The method of claim 23 wherein the indium material is characterized by a purity of about 99.99% or greater.

31. The method of claim 23 wherein the insert species is argon.

32. The method of claim 23 wherein the substrate and one or more target materials is biased between a DC power source.

33. The method of claim 23 wherein the DC power source ranges from about 100 W to about 150 W.

34. The method of claim 23 further comprising subjecting the copper indium disulfide layer to a thermal treatment process having a temperature greater than about 500 Degrees Celsius.

35. The method of claim 23 further comprising subjecting the copper indium disulfide layer to a thermal treatment process to increase a grain size to about one micron and greater and a resistivity 100 Ohm/cm² to 10 Ohm/cm² and less.

36. The method of claim 23 wherein the transparent substrate at least two feet in dimension and greater.

37. A method for forming a thin film photovoltaic device, the method comprising:
providing a substrate comprising a surface region;
forming a first electrode layer overlying the surface region;
forming a copper layer overlying the first electrode layer;
forming an indium layer overlying the copper layer to form a multi-layered structure;
subjecting at least the multi-layered structure to thermal treatment process in an environment containing a sulfur bearing species;
forming a copper indium disulfide material from at least the treatment process of the multi-layered structure, the copper indium disulfide material comprising a thickness ranging from 1 micron to 2 microns and a copper-to-indium atomic ratio from about 1.4:1 to about 1.6:1;
forming a window layer overlying the copper indium disulfide material; and
whereupon the copper indium disulfide material forms an absorber layer of a photovoltaic device characterized by an efficiency of about 10% and greater.

38. The method of claim 37 wherein the absorber layer comprises a thickness of about 1.5 microns.

39. The method of claim 37 wherein the absorber layer comprises copper indium disulfide material with copper-to-indium atomic ratio of about 1.5:1.

40. The method of claim 37 wherein the photovoltaic device is characterized by a current density versus bias voltage (I-V) monotonic curve comprising a short circuit current density of about 23.5 mA/cm² and an open circuit voltage of about 0.69 Volt.

41. A thin film photovoltaic device comprising:
a substrate comprising a surface region;
a first electrode layer overlying the surface region;
an absorber layer overlying the first electrode layer, the absorber layer comprising a copper indium disulfide material characterized by a thickness ranging from 1 micron to 2 microns and a copper-to-indium atomic ratio ranging from about 1.4:1 to about 1.6:1;
a window layer overlying the absorber layer; and
a characteristics of an energy conversion efficiency of about 10% and greater.

42. A thin film photovoltaic device comprising:
a transparent substrate comprising a surface region;
a first electrode layer overlying the surface region;
a copper indium disulfide material on the first electrode layer and transformed from at least a treatment process of a multi-layered structure comprising a copper layer overlying the first electrode layer and an indium layer overlying the copper layer, the copper indium disulfide material being characterized by a copper-to-indium atomic ratio ranging from about 1.35:1 to about 1.60:1; and
a window layer overlying the copper indium disulfide material.

43. The device of claim 42 wherein the device is bifacial.

44. The device of claim 42 further comprising a band gap energy ranging from about 1.45 eV to 1.5 eV and an efficiency of about 10% and greater characterizing a photovoltaic cell using the copper indium disulfide material.
